(19) United States
(12) Patent Application Publication
(10) Pub. No.: US 2023/0340323 A1
(43) Pub. Date: Oct. 26, 2023

(54) QUANTUM DOT LIGHT EMITTING MATERIAL, METHOD FOR MANUFACTURING THE SAME, AND DIFFUSION PLATE COMPRISING THE SAME

(71) Applicant: Skylight Inc., Hsinchu City (TW)

(72) Inventor: Yung-Wei HUANG, Hsinchu County (TW)

(21) Appl. No.: 18/305,604

(22) Filed: Apr. 24, 2023

(30) Foreign Application Priority Data
Apr. 25, 2022 (TW) 111115559

(51) Int. Cl. C09K 11/02; G02B 5/02; C09K 11/66

(52) U.S. Cl. CPC C09K 11/025; G02B 5/0242; G02B 5/0268; C09K 11/665; H10K 50/115

(57) ABSTRACT

A quantum dot light emitting material is provided, which includes: a core comprising an inorganic oxide; a quantum dot layer covering the core and comprising perovskite quantum dots; and a protection layer covering the quantum dot layer, wherein the protection layer comprises PbX(OH), and X is Cl, Br or I. In addition, a method for manufacturing the aforesaid quantum dot light emitting material is also provided. Moreover, a diffusion plate comprising the aforesaid quantum dot light emitting material is also provided.

### CROSS-REFERENCE TO RELATED APPLICATIONS

This application claims the benefits of the Taiwan Patent Application Serial Number 111115559, filed on Apr. 25, 2022, the subject matter of which is incorporated herein by reference.

### BACKGROUND OF THE INVENTION

### Field

The preset invention relates to a quantum dot light emitting material, a method for manufacturing the same and a diffusion plate comprising the same. More specifically, the present invention relates to a quantum dot light emitting material comprising perovskite quantum dots, a method for manufacturing the same and a diffusion plate comprising the same.

### Description of Related Art

Quantum dot material is one of the emerging luminescent materials in recent years. In particular, when the size of the quantum dot material is uniform, the emitted bandwidth is quite narrow and concentrated, which can replace the fluorescent powders in various existing light-emitting diode devices.

At present, the quantum dot material widely studied is cadmium selenide (CdSe). Since CdSe is easily damaged by oxygen and moisture, the CdSe material is usually coated with a zinc sulfide layer to form a quantum dot with a core-shell structure. This kind of CdSe quantum dot material with the core-shell structure is the most commonly used quantum dot material for commercialization at present.

However, CdSe quantum dot materials have the risk of causing environmental pollution due to heavy metals. Thus, many manufacturers tend to develop quantum dots without heavy metals to meet the needs of environmental protection.

Therefore, it is desirable to develop a novel quantum dot light emitting material without heavy metals, a method for manufacturing the same and a diffusion plate comprising the same.

### SUMMARY OF THE INVENTION

The present invention relates to a quantum dot light emitting material, a method for manufacturing the same and a diffusion plate comprising the same. By using the quantum dot light emitting material with the special structure disclosed in the present invention, the effect of the diffusion plate can be improved.

The quantum dot light emitting material of the present invention comprises: a core comprising an inorganic oxide; a quantum dot layer covering the core and comprising perovskite quantum dots; and a protection layer covering the quantum dot layer, wherein the protection layer comprises PbX(OH), and X is Cl, Br or I.

In one embodiment of the present invention, the core may be consisted of an inorganic oxide. Examples of the inorganic oxide include, but are not limited to, silica, titania, silica-titania, zinc oxide, zirconia, alumina or a combination thereof. In one embodiment of the present invention, the inorganic oxide is silica. In another embodiment of the present invention, the inorganic oxide is fumed silica. In further another embodiment of the present invention, the core may be a particle formed by the aggregation of a plurality of silica nanoparticles.

In one embodiment of the present invention, a particle size of the core may range from 10 nm to 1 μm, for example, from 10 nm to 900 nm, 10 nm to 800 nm, 10 nm to 700 nm, 10 nm to 600 nm, 10 nm to 500 nm, 10 nm to 400 nm or 10 nm to 300 nm, but the present invention is not limited thereto. In one embodiment of the present invention, the particle size of the core may refer to an average particle size of the core.

In one embodiment of the present invention, the core may have a regular shape (for example, spherical) or an irregular shape. In one embodiment of the present invention, the material of the core may be fumed silica, thus the core may have an irregular shape. However, the present invention is not limited thereto.

In one embodiment of the present invention, the quantum dot layer may cover the core, wherein the quantum dot layer may directly or indirectly cover the core. In one embodiment of the present invention, the quantum dot layer may directly cover the core. More specifically, the surface of the core has not been modified, and the quantum dot layer may directly contact and cover the surface of the core.

In one embodiment of the present invention, the quantum dot layer may comprise perovskite quantum dots. In another embodiment of the present invention, the quantum dot layer may be consisted of perovskite quantum dots. Various quantum dots are currently known, such as CdSe/ZnS quantum dots with a core-shell structure; but such quantum dots are not suitable for the present invention. In the present invention, quantum dot precursors can be deposited on the surface of the core through a process such as a solution method to form the quantum dot light emitting material of the present invention, but the CdSe/ZnS quantum dots with the core-shell structure are not suitable for such process. Thus, in the present invention, the quantum dot layer is consisted of perovskite quantum dots.

In one embodiment of the present invention, the perovskite quantum dots may be organic metal halides, inorganic metal halides, or a combination thereof. The organic or inorganic metal halides may be a compound having the formula of MaAbXc. M may be an organic or inorganic ion, such as an amine ion (for example, methylamine ion or ethylamine ion), an amidine ion (for example, formamidine ion or acetamidine ion), or a metal cation (for example, cesium ion). A may be a metal ion, such as a lead ion, a tin ion, a bismuth ion or a germanium ion. X may be a halide ion such as chloride, bromide or iodide. a may be an integer of 1 to 7, b may be an integer of 1 to 4, and c may be an integer of 3 to 9. In one embodiment of the present invention, a and b may be 1, and c may be 3. In another embodiment of the present invention, a may be 4, b may be 1, and c may be 6.

In one embodiment of the present invention, examples of perovskite quantum dots may include, but are not limited to CH₃NH₃PbCl₃, CH₃NH₃PbBr₃, CH₃NH₃PbI₃, CH₃NH₃PbICl₂, CH₃NH₃PbI₂Cl, CH₃NH₃PbIBr₂, CH₃NH₃PbI₂Br, CH₃NH₃PbIClBr, HC(═NH)NH₃PbCl₃, HC(═NH)NH₃PbBr₃, HC(═NH)NH₃PbI₃, HC(═NH)NH₃PbICl₂, HC(═NH)NH₃PbI₂Cl, HC(═NH)NH₃PbIBr₂, HC(═NH)NH₃PbI₂Br, HC(═NH)NH₃PbIClBr, CsPbCl₃, CsPbBr₃, CsPbI₃, CsPbICl₂, CsPbI₂Cl, CsPbIBr₂, CsPbI₂Br and/or CsPbIClBr.

In one embodiment of the present invention, the perovskite quantum dots may be inorganic metal halides. In one embodiment of the present invention, the perovskite quantum dots being the inorganic metal halides may be represented by the following formula (I):

Csₐ(Pb_{1-d}M′_{d})_{b}X_{c} (I)

wherein each X is independently Cl, Br or I, M′ is Sn, Ge or a combination thereof, a is an integer from 1 to 7, b is an integer from 1 to 4, c is an integer from 3 to 9, and d is between 0 to 0.9. In one embodiment of the present invention, the perovskite quantum dots represented by the formula (I) may be CsPb_{1-d}M′_{d}Br₃.

In one embodiment of the present invention, the perovskite quantum dots may be inorganic metal halides. In one embodiment of the present invention, the perovskite quantum dots being the inorganic metal halides may be represented by the following formula (II):

CsₐPb_{b}X_{c} (II)

wherein each X is independently Cl, Br or I, a is an integer from 1 to 7, b is an integer from 1 to 4, and c is an integer from 3 to 9. In one embodiment of the present invention, a and b may be 1, and c may be 3. In another embodiment of the present invention, a may be 4, b may be 1, and c may be 6.

In one embodiment of the present invention, examples of perovskite quantum dots may be CsPbBr₃, CsPb₂Br₅ or Cs₄PbBr₆; but the present invention is not limited thereto.

In one embodiment of the present invention, the quantum dot layer may be a layer consisting of a plurality of perovskite quantum dot particles. The particle size of the perovskite quantum dot particles may range from 1 nm to 50 nm, for example, may range from 2 nm to 50 nm, 3 nm to 50 nm, 4 nm to 50 nm, 5 nm to 50 nm, 5 nm to 45 nm, 5 nm to 40 nm, 5 nm to 35 nm, 5 nm to 30 nm, 5 nm to 25 nm, 8 nm to 25 nm, 8 nm to 20 nm or 10 nm to 20 nm, but the present invention is not limited thereto. In one embodiment of the present invention, the particle size of the perovskite quantum dot particles may refer to the average particle size of the perovskite quantum dot particles.

In the present invention, the ratio of the material of the core to the material of the quantum dots may be adjusted according to the need. In one embodiment of the present invention, the weight ratio of the material of the core to the material of the quantum dots may range from 0.5:1 to 1000:1, for example, may range from 0.5:1 to 800:1, 0.5:1 to 500:1, 0.5:1 to 300:1, 0.5:1 to 100:1, 1:1 to 100:1, 1:1 to 80:1, 1:1 to 50:1, 1:1 to 30:1, 5:1 to 30:1, 5:1 to 20:1, 5:1 to 15:1, 5:1 to 12.5:1 or 7.5:1 to 12.5:1. In one embodiment of the present invention, the weight ratio of the material of the core to the material of the quantum dots may be about 10:1.

In one embodiment of the present invention, the protection layer may cover the quantum dot layer. The protection layer may directly or indirectly cover the quantum dot layer. In one embodiment of the present invention, the protection layer may directly cover the quantum dot layer. In addition, in the present invention, the protection layer may have a single-layer or multi-layer structure. Since perovskite quantum dots are highly sensitive to oxygen and moisture, by providing a protective layer, the stability of the formed quantum dot light emitting material can be improved, or the formed quantum dot light emitting material can be stored more easily. In one embodiment of the present invention, examples of the material of the protection layer may be PbBr(OH), but the present invention is not limited thereto. When the quantum dot layer is directly coated with PbBr(OH) to form a PbBr(OH) protection layer, the PbBr(OH) protection layer may selectively be coated with other protection materials, such as an inorganic oxide (for example, a metal oxide such as alumina), an organic polymer, or a combination thereof.

In addition to the aforesaid quantum dot light emitting material, the present invention further provides a method for preparing the quantum dot light emitting material, which comprises the following steps: providing a quantum dot particle, wherein the quantum dot particle comprises: a core comprising an inorganic oxide; and a quantum dot layer covering the core and comprising perovskite quantum dots; and mixing the quantum dot particle with an organic solution to form a protection layer on the quantum dot layer, wherein the protection layer comprises PbX(OH), X is Cl, Br or I, and the organic solution comprises an organic acid and an organic amine.

In one embodiment of the present invention, the organic solution may further comprise lead halide. Examples of the lead halide include, but are not limited to PbF₂, PbCl₂, PbBr₂, PbI₂ or a combination thereof. In one embodiment of the present invention, the lead halide may be PbBr₂.

In one embodiment of the present invention, the organic acid may be R₁—COOH and the organic amine may be R₂—NH₂; wherein R₁ may be C₁₋₁₀ alkyl and R₂ may be C₁₋₁₂ alkyl. In the present invention, the term “alkyl” includes straight and branched alkyl groups.

In one embodiment of the present invention, R₁ may be C₂₋₁₀ alkyl, C₃₋₁₀ alkyl, C₄₋₁₀ alkyl, C₄₋₉ alkyl, C₄₋₈ alkyl, C₄₋₇ alkyl or C₅₋₇ alkyl. In one embodiment of the present invention, the organic acid may be n-hexanoic acid.

In one embodiment of the present invention, R₂ may be C₂₋₁₂ alkyl, C₃₋₁₂ alkyl, C₄₋₁₂ alkyl, C₅₋₁₂ alkyl, C₆₋₁₂ alkyl, C₆₋₁₁ alkyl, C₆₋₁₀ alkyl, C₆₋₉ alkyl or C₇₋₉ alkyl. In one embodiment of the present invention, the organic amine may be n-octylamine.

In addition to the aforementioned quantum dot light emitting material, the present invention also provides a diffusion plate, which comprises: a substrate; and the aforesaid quantum dot light emitting material dispersed in the substrate. The material of the substrate may be the material of the diffusion plate commonly used in the art, for example, polymethyl methacrylate (PMMA), cycloolefin polymer (COP), polycarbonate Esters (PC) or a combination thereof.

The diffusion plate of the present invention may be formed by injection molding or other molding methods after mixing the aforementioned quantum dot light emitting material with the material of the substrate. In addition, the diffusion plate of the present invention may be used together with a light source. When the diffusion plate of the present invention is used together with the light source, the diffusion plate may be disposed on the light emitting side of the light source.

In one embodiment of the present invention, the diffusion plate may further comprise diffusion particles dispersed in the substrate. Herein, the material of the diffusion particles may be the diffusion material commonly used in the art, such as polymer particles, air bubbles or a combination thereto.

In addition to the aforementioned quantum dot light emitting material, the present invention further provides a light emitting diode device, which comprises: a light emitting layer comprising the aforementioned quantum dot light emitting material. In addition, the light emitting diode device of the present invention may further comprise a light emitting diode chip, and the light emitting layer is disposed on the light emitting diode chip. In one embodiment of the present invention, the light emitting diode chip may be a blue-light emitting diode chip or a UV-light emitting diode chip.

The application of the light emitting diode device of the present invention is not particularly limited, as long as it is an electronic device that needs to emit light. For example, the light emitting diode device can be used in lamps, display units of display devices, backlight devices, or other electronic devices that need to emit light. Examples of display devices may include mobile phones, notebook computers, video cameras, cameras, music players, mobile navigation devices, televisions, etc., but the present invention is not limited thereto.

Other novel features of the present invention will become more apparent from the following detailed description when taken in conjunction with the accompanying drawings.

### BRIEF DESCRIPTION OF DRAWINGS

FIG. 1 is a schematic diagram of a quantum dot light emitting material according to Embodiment 1 of the present invention.

FIG. 2 is a schematic diagram of a quantum dot light emitting material according to Embodiment 2 of the present invention.

FIG. 3 is a schematic cross-sectional view of a light emitting diode device according to Embodiment 3 of the present invention.

FIG. 4 is a schematic cross-sectional view of a diffusion plate according to one embodiment of the present invention.

### DETAILED DESCRIPTION OF THE INVENTION

Different embodiments of the present invention are provided in the following description. These embodiments are meant to explain the technical content of the present invention, but not meant to limit the scope of the present invention. A feature described in an embodiment may be applied to other embodiments by suitable modification, substitution, combination, or separation.

It should be noted that, in the present specification, when a component is described to have an element, it means that the component may have one or more of the elements, and it does not mean that the component has only one of the element, except otherwise specified.

In the present specification, except otherwise specified, the feature A “or” the feature B means the existence of the feature A or the existence of the feature B. The feature A “and/or” the feature B means the existence of the feature A, the existence of the feature B, or the existence of both the features A and B. The feature A “and” the feature B means the existence of both the features A and B. The term “comprise(s)”, “comprising”, “include(s)”, “including”, “have”, “has” and “having” means “comprise(s)/comprising but is/are/being not limited to”.

Moreover, in the present specification, the terms, such as “on”, “above”, “under”, “below”, or “between”, are used to describe the relative positions among a plurality of elements, and the described relative positions may be interpreted to include their translation, rotation, or reflection.

Furthermore, except otherwise specified, the terms recited in the specification and the claims such as “above”, “over”, or “on” are intended not only directly contact with the other element, but also intended indirectly contact with the other element. Similarly, the terms recited in the specification and the claims such as “below”, or “under” are intended not only directly contact with the other element but also intended indirectly contact with the other element.

In the present specification, the terms “almost”, “about” and “approximately” mean within ±20%, within ±10%, within ±5%, within ±3%, within ±2%, within ±1%, or within ±0.5% of a given value or range. The quantity given here is an approximate quantity, that is, without specifying “almost”, “about” and “approximately”, it can still imply “almost”, “about” and “approximately”.

In the present specification, except otherwise specified, the terms (including technical and scientific terms) used herein have the meanings generally known by a person skilled in the art. It should be noted that, except otherwise specified in the embodiments of the present invention, these terms (for example, the terms defined in the generally used dictionary) should have the meanings identical to those known in the art, the background of the present invention or the context of the present specification, and should not be read by an ideal or over-formal way.

### Embodiment 1

1 mmol of CsBr and 1 mmol of PbBr₂ were dissolved in 50 ml of dimethyl sulfoxide (DMSO), followed by adding 100 μl of hexadecyltrimethoxysilane (HDTMS). After mixing and stirring for 1 hour, 0.5 g of fumed silica was added, followed by stirring. After mixing and stirring for 1 hour, the mixture was placed at 150° C. for evaporating the organic solvent DMSO and drying to form the quantum dot particle. Then, the quantum dot particle was mixed with an organic solution which was prepared by mixing 0.1 ml of n-hexanoic acid, 0.1 ml of n-octylamine and 10 ml of water, to form PbBr(OH) on the quantum dot layer. Thus, the quantum dot light emitting material of the present embodiment was obtained.

After the aforesaid process, the quantum dot light emitting material of the present embodiment was obtained.

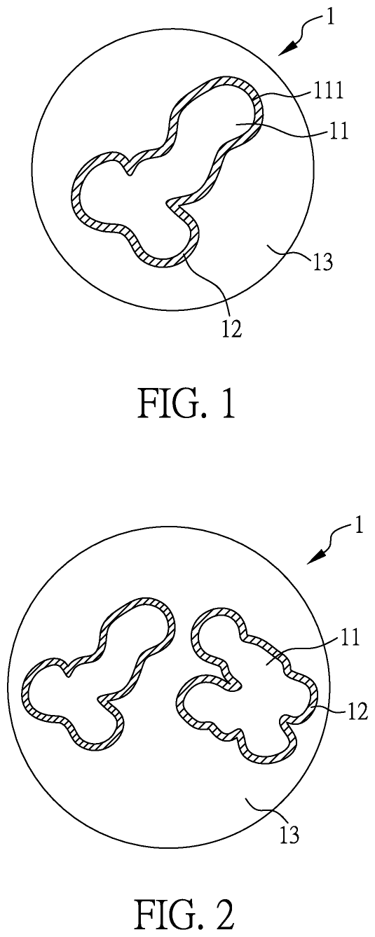

FIG. 1 is a schematic diagram of the quantum dot light emitting material of the present embodiment. As shown in FIG. 1, the quantum dot light emitting material 1 of the present embodiment comprises: a core 11 comprising an inorganic oxide; a quantum dot layer 12 covering the core 11 and comprising perovskite quantum dots; and a protection layer 13 covering the quantum dot layer 12, wherein the protection layer 13 comprises PbX(OH), and X is Cl, Br or I. In the present embodiment, the core 11 is a core formed by fumed silica, which has an irregular shape, and the average diameter of the core 11 is about 10 nm to 300 nm. In addition, in the present embodiment, the quantum dot layer 12 directly covers the surface 111 of the core 11. More specifically, the quantum dot layer 12 directly covers the unmodified surface 111 of the core 11. Furthermore, the quantum dot layer 12 is consisted of CsPbBr₃ quantum dots. More specifically, the quantum dot layer 12 is consisted of CsPbBr₃ quantum dot particles, and the average particle size of the CsPbBr₃ quantum dot particles is about 1 nm to 50 nm. Moreover, the protection layer 13 is consisted of PbBr(OH), which may completely cover the whole surface of the quantum dot layer 12 to protect the quantum dot layer 12.

### Embodiment 2

The method for preparing the quantum dot light emitting material of the present embodiment is similar to that disclosed in Embodiment 1, except that the used organic solution was prepared by mixing 0.1 ml of n-hexanoic acid, 0.1 ml of n-octylamine, 100 mg of PbBr₂ and 20 ml of water.

The quantum dot light emitting material of the present embodiment is similar to that prepared in Embodiment 1, except that the protection layer 13 covers plural cores 11 coated with the quantum dot layers 12, as shown in FIG. 2.

As mentioned above, the perovskite quantum dot light emitting materials of Embodiments 1 and 2 can be prepared by using a perovskite quantum dot precursor as a raw material and combining an inorganic oxide material (fumed silica in the present embodiments) and a dispersant, and the perovskite quantum dots can be directly deposited on the surface of the inorganic oxide. Thus, the quantum dot light emitting material of the present embodiments can be synthesized in one step. However, in the conventional methods of synthesizing quantum dots, no matter the conventional CdSe core-shell quantum dots or perovskite quantum dots, they all need to be prepared through complicated heat injection and reaction procedures. In addition, the concentration of the reactants, and the time and temperature of reaction have to be precisely controlled to control the particle size of quantum dots; and if there is a slight difference, the luminescent wavelength will change, making the yield difficult to control.

In addition, the light emitting structure of the previously synthesized CdSe core-shell quantum dots or perovskite quantum dots has to be stabilized by the ligands absorbed on the surface of the quantum dots. However, once exposed to light or thermal reaction, the ligands on the surface of the quantum dots are easy to fall off, resulting in a light quenching effect, which causes a significant decrease in luminous efficiency. In the perovskite quantum dot light emitting materials of Embodiments 1 and 2, the perovskite quantum dots are not formed on the inorganic oxide material through ligands, but the perovskite quantum dots are directly formed on the inorganic oxide material. In addition, in Embodiments 1 and 2, the perovskite quantum dots itself can react with PbBr(OH) to form the protection layer, so it is possible to obtain the quantum dot materials with the functions of waterproof, light-resistant, and heat-resistant in a simple and fast way.

### Embodiment 3

FIG. 3 is a schematic cross-sectional view of a light emitting diode device according to Embodiment 3 of the present invention. As shown in FIG. 3, the light emitting diode device of the present embodiment comprises: a light emitting diode chip 21, wherein two electrodes 22 are respectively disposed on a surface of the light emitting diode chip 21; and a light emitting layer 23 disposed on the surfaces of the light emitting diode chip 21 without the electrodes 22 disposed thereon. Herein, the light emitting layer 23 can be prepared by mixing silicone and the quantum dot light emitting material 1 prepared in Embodiment 1, followed by applying on the surfaces of the light emitting diode chip 21.

In other embodiments of the present invention, the quantum dot light emitting material 1 prepared in Embodiment 1 may be directly formed on the surfaces of the light emitting diode chip 21 without using silicone.

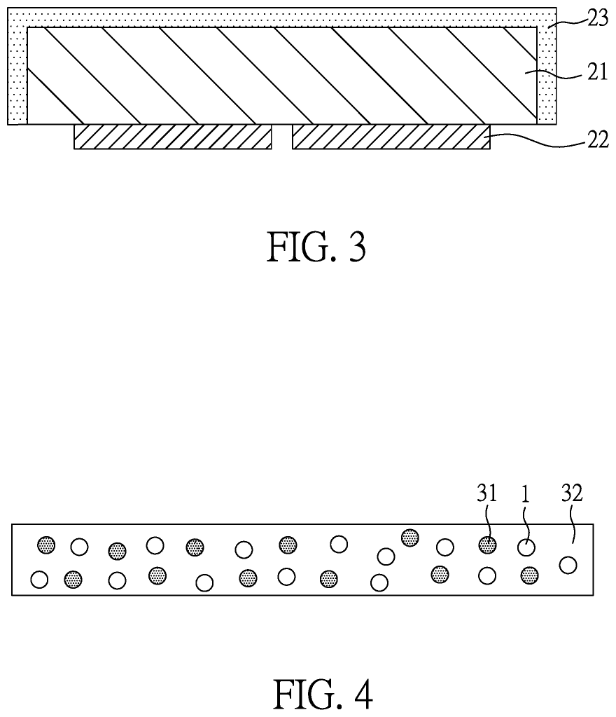

FIG. 4 is a schematic cross-sectional view of a diffusion plate according to one embodiment of the present invention.

As shown in FIG. 4, the diffusion plate of the present embodiment comprises: a substrate 32; the quantum dot light emitting material 1 of Embodiment 1 dispersed in the substrate 32; and diffusion particles 31 dispersed in the substrate 32.

In the present invention, by providing a quantum dot light emitting material with a novel structure, the luminous efficiency of the quantum dots can be effectively improved, especially the luminous efficiency of the perovskite quantum dots can be improved, so that the application field of the perovskite quantum dots can be extended.

In the present invention, as long as the features of the various embodiments do not violate the spirit of the invention or conflict, they can be mixed and matched arbitrarily.

Although the present invention has been explained in relation to its embodiment, it is to be understood that many other possible modifications and variations can be made without departing from the spirit and scope of the present invention as hereinafter claimed.

In addition, the above-mentioned embodiments are only examples for convenience of description, and the scope claimed by the present invention shall be subject to the claims of the patent application, rather than limited to the above-mentioned embodiments.

1. A quantum dot light emitting material, comprising:
a core comprising an inorganic oxide;
a quantum dot layer covering the core and comprising perovskite quantum dots; and
a protection layer covering the quantum dot layer, wherein the protection layer comprises PbX(OH), and X is Cl, Br or I.

2. The quantum dot light emitting material of claim 1, wherein the inorganic oxide is silica, titania, silica-titania, zinc oxide, zirconia, alumina or a combination thereof.

3. The quantum dot light emitting material of claim 2, wherein the inorganic oxide is silica.

4. The quantum dot light emitting material of claim 3, wherein the inorganic oxide is fumed silica.

5. The quantum dot light emitting material of claim 1, wherein the perovskite quantum dots are organic metal halides, inorganic metal halides, or a combination thereof.

6. The quantum dot light emitting material of claim 5, wherein the perovskite quantum dots are inorganic metal halides.

7. The quantum dot light emitting material of claim 6, wherein the inorganic metal halides are represented by the following formula (I):
Csₐ(Pb_{1-d}M′_{d})_{b}X_{c} (I)
wherein each X is independently Cl, Br or I, M′ is Sn, Ge or a combination thereof, a is an integer from 1 to 7, b is an integer from 1 to 4, c is an integer from 3 to 9, and d is between 0 to 0.9.

8. The quantum dot light emitting material of claim 6, wherein the inorganic metal halides are represented by the following formula (II):
CsₐPb_{b}X_{c} (II)
wherein each X is independently Cl, Br or I, a is an integer from 1 to 7, b is an integer from 1 to 4, and c is an integer from 3 to 9.

9. The quantum dot light emitting material of claim 8, wherein the inorganic metal halides are CsPbBr₃.

10. The quantum dot light emitting material of claim 1, wherein the protection layer comprises PbBr(OH).

11. A method for manufacturing a quantum dot light emitting material, comprising the following steps:
providing a quantum dot particle, wherein the quantum dot particle comprises: a core comprising an inorganic oxide; and a quantum dot layer covering the core and comprising perovskite quantum dots; and
mixing the quantum dot particle with an organic solution to form a protection layer on the quantum dot layer, wherein the protection layer comprises PbX(OH), X is Cl, Br or I, and the organic solution comprises an organic acid and an organic amine.

12. The method of claim 11, wherein the organic solution further comprises lead halide.

13. The method of claim 11, wherein the protection layer comprises PbBr(OH).

14. The method of claim 11, wherein the inorganic oxide is silica, titania, silica-titania, zinc oxide, zirconia, alumina or a combination thereof.

15. The method of claim 11, wherein the perovskite quantum dots are inorganic metal halides.

16. The method of claim 15, wherein the inorganic metal halides are represented by the following formula (I):
Csₐ(Pb_{1-d}M′_{d})_{b}X_{c} (I)
wherein each X is independently Cl, Br or I, M′ is Sn, Ge or a combination thereof, a is an integer from 1 to 7, b is an integer from 1 to 4, c is an integer from 3 to 9, and d is between 0 to 0.9.

17. The method of claim 15, wherein the inorganic metal halides are represented by the following formula (II):
CsₐPb_{b}X_{c} (II)
wherein each X is independently Cl, Br or I, a is an integer from 1 to 7, b is an integer from 1 to 4, and c is an integer from 3 to 9.

18. The method of claim 11, wherein the organic acid is R₁—COOH and the organic amine is R₂—NH₂; wherein R₁ is C₁₋₁₀ alkyl and R₂ is C₁₋₁₂ alkyl.

19. A diffusion plate, comprising:
a substrate; and
a quantum dot light emitting material dispersed in the substrate and comprising:
a core comprising an inorganic oxide;
a quantum dot layer covering the core and comprising perovskite quantum dots; and
a protection layer covering the quantum dot layer, wherein the protection comprises PbX(OH), and X is Cl, Br or I.

20. The diffusion plate of claim 19, further comprising: diffusion particles dispersed in the substrate.
